(19) United States
(12) Patent Application Publication
(10) Pub. No.: US 2026/0358417 A1
(43) Pub. Date: Nov. 12, 2026

(54) ARC FAULT CIRCUIT INTERRUPTER TESTER

(71) Applicant: Harbor Freight Tools USA, Inc., Calabasas, CA (US)

(72) Inventor: Bruce R. Kuhn, Naperville, IL (US)

(73) Assignee: Harbor Freight Tools USA, Inc., Calabasas, CA (US)

(21) Appl. No.: 19/669,676

(22) Filed: May 6, 2026

Related U.S. Application Data
(60) Provisional application No. 63/801,623, filed on May 7, 2025.

(51) Int. Cl. G01R 31/327; G01K 3/00; H02H 3/08

(52) U.S. Cl. CPC G01R 31/327; G01K 3/005; H02H 3/085

(57) ABSTRACT

At least one embodiment relates to an arc fault circuit interrupter device testing system, comprising a housing, a load switching circuit disposed within the housing configured to receive a first signal and a second signal, and a controller disposed within the housing operatively coupled to the load switching circuit. The controller may comprise one or more processors configured to cause adjustment of a frequency of the second signal, and generate a test signal comprising an overlay of the first signal with the second signal.

### CROSS REFERENCE TO RELATED PATENT APPLICATION

This application claims the benefit of and priority to U.S. Provisional Patent Application No. 63/801,623, filed May 7, 2025, which is incorporated herein by reference in its entirety.

### BACKGROUND

Electrical arcing occurs when electricity jumps a gap (e.g., space) in a circuit. Parallel arcing is a type of electrical arcing that occurs when electricity jumps a gap between separate wires at different voltages. In some instances, parallel arcing can occur due to physical damage to wire insulation that separates two wires. Series arcing is a type of electrical arcing that occurs when electricity jumps a gap between a single wire. For example, a damaged (e.g., frayed, separated) wire strand might cause a gap in the wire for electricity to jump across. An arc fault circuit interrupter (AFCI) monitors an electrical circuit to detect unwanted or dangerous arcing conditions and interrupts the circuit if such arcing conditions are detected. Many building codes may require AFCIs to be installed in homes and commercial buildings, and such AFCIs may need to be periodically tested to ensure their functionality. However, it can be difficult to simulate unwanted or dangerous arcing to test such AFCIs, and existing AFCIs often do not respond to the same simulated arcing condition. Additionally, existing testing devices may require two separate load switching circuits to control high and low current loads, which increases circuit complexity and the number of input/output (I/O) pins required.

### SUMMARY OF THE INVENTION

At least one embodiment relates to an arc fault circuit interrupter (AFCI) device testing system, comprising a housing, a load switching circuit disposed within the housing configured to receive a first signal and a second signal, and a controller disposed within the housing operatively coupled to the load switching circuit. The controller may comprise one or more processors configured to cause adjustment of a frequency of the second signal, and generate a test signal comprising an overlay of the first signal with the second signal.

In some embodiments, the load switching circuit is configured to receive an alternating current (AC) signal, and wherein the system comprises a rectifier configured to adjust one or more negative half cycles of the AC signal such that the one or more negative half cycles have a positive voltage.

In some embodiments, the controller may generate the test signal by selecting at least one half cycle of a plurality of half cycles of the first signal.

In some embodiments, the system comprises a temperature sensor configured to monitor a temperature of at least one of the load switching circuit or the housing, and the one or more processors are configured to receive temperature data from the temperature sensor, determine whether the temperature data is above a predetermined threshold, and disable the load switching circuit, responsive to a determination that the temperature data is above the predetermined threshold.

In some embodiments, the frequency is a first frequency, wherein the controller is configured to adjust the frequency of the second signal to be a second frequency, and wherein the first frequency is different from the second frequency.

In some embodiments, the test signal comprises a first pulse of the first signal overlayed with a second pulse of the second signal, and wherein a pulse width of the first pulse is equal to a pulse width of the second pulse.

In some embodiments, a pulse width of the test signal is between 4 milliseconds and 6 milliseconds.

In some embodiments, an amplitude of the first signal is larger than an amplitude of the second signal.

In some embodiments, the system includes an interface configured to electronically couple the load switching circuit and an AFCI device located externally of the housing, wherein the one or more processors are configured to transmit the test signal to the AFCI device.

Another embodiment relates to a method for testing arc fault circuit interrupter (AFCI) devices. The method includes receiving, by one or more processors of a load switching circuit, a first signal and a second signal, causing, by the one or more processors, adjustment of a frequency of the second signal, determining, by the one or more processors, a desired pulse pattern for a test signal comprising the first signal and the second signal, and generating, by the one or more processors, the test signal at the desired pulse pattern, the test signal comprising an overlay of the first signal with the second signal.

In some embodiments, the method includes selecting, by the one or more processors, one or more half cycles of the first signal to be included in the desired pulse pattern for the test signal.

In some embodiments, the frequency is a first frequency, comprising adjusting, by the one or more processors, the frequency of the second signal to be a second frequency, wherein the first frequency and the second frequency are different.

In some embodiments, the method includes receiving, by the one or more processors, temperature data from a temperature sensor, determining, by the one or more processors, whether the temperature data is above a predetermined threshold, and disabling, by the one or more processors, the load switching circuit, responsive to a determination that the temperature data is above the predetermined threshold.

In some embodiments, the test signal comprises a first pulse of the first signal and a second pulse of the second signal, comprising synchronizing, by the one or more processors, switching of the first signal and the second signal, such that a pulse width of the first pulse is equal to a pulse width of the second pulse.

In some embodiments, the method includes transmitting, by the one or more processors, the test signal to an AFCI device located externally of a housing where the one or more processors are disposed.

In some embodiments, the frequency of the second signal is adjusted to be a higher frequency than the first signal.

In some embodiments, the test signal is a first test signal, the frequency is a first frequency, and the desired pulse pattern is a first desired pulse pattern, and the method includes determining, by the one or more processors, whether the first test signal activated an AFCI device, at least one of (a) adjusting, by the one or more processors, the frequency of the second signal to be a second frequency, or (b) adjusting, by the one or more processors, the desired pulse pattern to be a second desired pulse pattern, and generating, by the one or more processors, the test signal at the second desired pulse pattern.

Another embodiment relates to one or more non-transitory storage media storing instructions thereon that, when executed by one or more processors, cause the one or more processors to perform operations comprising receiving a first signal and a second signal, causing adjustment of a frequency of the second signal, determining a desired pulse pattern for a test signal comprising the first signal and the second signal, and generating the test signal at the desired pulse pattern, the test signal comprising an overlay of the first signal with the second signal.

In some embodiments, the test signal is a first test signal, the frequency is a first frequency, and the desired pulse pattern is a first desired pulse pattern, and the instructions cause the one or more processors to perform operations comprising determining whether the first test signal activated an arc fault circuit interrupter (AFCI) device, at least one of (a) adjusting the frequency of the second signal to be a second frequency, or (b) adjusting the desired pulse pattern to be a second desired pulse pattern, and generating, by the one or more processors, the test signal at the second desired pulse pattern.

In some embodiments, the test signal comprises a first pulse of the first signal and a second pulse of the second signal, and wherein the instructions cause the one or more processors to perform operations comprising synchronizing, by the one or more processors, switching of the first signal and the second signal, such that a pulse width of the first pulse is equal to a pulse width of the second pulse.

### BRIEF DESCRIPTION OF THE DRAWINGS

The disclosure will become more fully understood from the following detailed description, taken in conjunction with the accompanying figures, wherein like reference numerals refer to like elements, in which:

FIG. 1 is a schematic block diagram of an AFCI device testing environment including an AFCI device testing system and an AFCI device, according to an example embodiment.

FIG. 2A is a graph showing a high load waveform and a low load waveform, according to an example embodiment.

FIG. 2B is a graph showing an overlay of the high load waveform and the low load waveform of FIG. 2A generated by the AFCI device testing system of FIG. 1, according to an example embodiment.

FIG. 3 is a flow diagram of a method for generating a signal for testing AFCI devices, according to an example embodiment.

FIG. 4 is a flow diagram of a method for testing AFCI devices, according to an example embodiment.

### DETAILED DESCRIPTION

Before turning to the figures, which illustrate certain exemplary embodiments in detail, it should be understood that the present application is not limited to the details or methodology set forth in the description or illustrated in the figures. It should also be understood that the terminology is for the purpose of description only and should not be regarded as limiting.

Referring generally to the FIGURES, an arc fault circuit interrupter (AFCI) device is a type of circuit breaker that may open (e.g., break, interrupt, etc.) a circuit when electrical arcing of a certain type (e.g., parallel, series) is detected. Embodiments of AFCI testing systems described herein are configured to test AFCI devices by imitating (e.g., recreating, resembling, simulating) arcing signals including parallel arcing signals or series arcing signals. One embodiment includes an AFCI testing system disposed in a housing. The AFCI testing system includes circuitry to generate a high load current signal and a low load current signal. The system may adjust the frequency of the low load current signal to imitate noise when overlayed with the high load current signal to create a test signal. The system may select a pulsing pattern and a pulse width for the test signal. The pulsing pattern may be based on selecting a plurality of half cycles for generating pulses of a determined width. The system may adjust the pulsing pattern, pulse width, and/or frequency of the second signal based on operator feedback and/or automatic decisions made by the system. Beneficially, the circuitry may be simplified by using a single driver circuit to control both the high load current signal and the low load current signal, which reduces the number of I/O pins required compared to systems using two separate driver circuits.

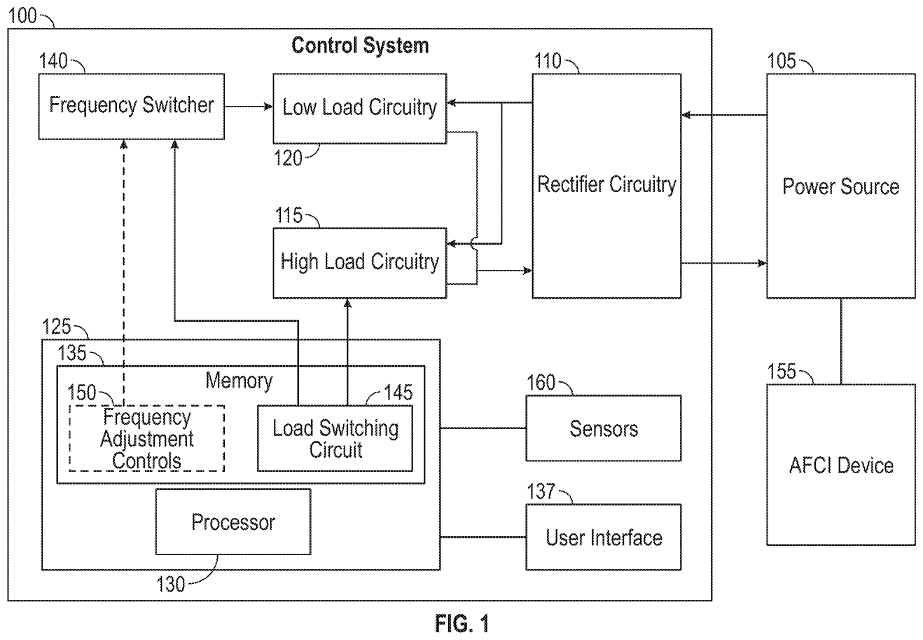

Referring to FIG. 1, depicted is an environment for AFCI device testing. The environment is shown to include a control system 100 configured to generate a test signal for testing an AFCI device 155. The control system 100 and components thereof may be disposed within a housing (e.g., body) configured to contain the control system 100 and allow the control system 100 to electronically couple to the AFCI device 155. The housing may be constructed of metal, plastic or a different durable material to at least partially enclose the control system 100 and/or related circuitry or hardware. The control system 100 is shown to receive or otherwise accept electricity from a power source 105. In some embodiments, the power source 105 may transmit (e.g., provide) an alternating current (AC) signal (e.g., electrical signal) to the control system 100. By way of example, the power source 105 may be an electrical outlet (e.g., 120V AC, 220V AC). By way of another example, the power source 105 may provide a 60 hertz (Hz) electrical signal to the control system 100. The power source 105 may include or otherwise be electronically coupled to the AFCI device 155, such that the power source 105, control system 100, and the AFCI device 155 are electronically coupled within a single circuit. For example, the power source 105 may be an electrical outlet, and the AFCI device 155 may be configured to test arcing associated with devices electrically coupled to the electrical outlet. The control system 100 may include a connection interface (e.g., plug, connector, etc.) to electronically couple the control system 100 to the power source 105. In some embodiments, the connection interface may be located externally of the housing and provide access to components (e.g., circuitry) within the housing.

The control system 100 is shown to include rectifier circuitry 110. The rectifier circuitry 110 may alter or otherwise transform the AC electricity received from the power source 105. In some embodiments, the rectifier circuitry 110 may transform an electrical signal from the power source 105 such that both the positive and negative half cycles of the signal have a positive voltage. By transforming the negative half cycle to have a positive voltage, the rectifier circuitry 110 may convert the AC signal from the power source 105 into a pulsating direct current (DC) signal. In some embodiments, the rectifier circuitry 110 includes a full bridge rectifier including diodes and/or other circuitry to transform the negative half cycle. In some embodiments, the rectifier circuitry 110 includes a smoothing capacitor or other circuitry configured to reduce (e.g., minimize, weaken) a ripple voltage of the converted signal.

The control system 100 is shown to include high load circuitry 115. The high load circuitry 115 is shown to be electronically coupled to the rectifier circuitry 110. The high load circuitry 115 may generate or otherwise produce a high load current signal using electricity provided by the rectifier circuitry 110. By way of example, the high load circuitry 115 may include a resistor or other circuit component to produce a consistent (e.g., periodic), high load current signal. In some embodiments, the high load circuitry 115 includes a 1.3 Ω resistor. In other embodiments, the high load circuitry 115 includes a resistor of a different resistance. As referred to herein, the high load current signal is a current signal with a larger magnitude than the low load current signal described in further detail below.

The control system 100 is shown to include low load circuitry 120. The low load circuitry 120 is shown to be electronically coupled to the rectifier circuitry 110, and is configured to generate or otherwise produce a low load current signal (e.g., relative to the high load current signal of the high load circuitry 115) using electricity provided by the rectifier circuitry 110. By way of example, the low load circuitry 120 may include a resistor or other circuit component configured to produce a consistent (e.g., periodic) low load current signal. In some embodiments, the low load circuitry 120 includes a 10 Ω resistor. In other embodiments, the low load circuitry 120 includes a resistor of a higher resistance than the resistor of the high load circuitry 115. It should be understood that the high load current signal has a larger magnitude than the low load current signal. For example, the high load circuitry 115 may include a first resistor of a first resistance, and the low load circuitry 120 may include a second resistor of a second resistance that is larger than the first resistance. When an equal voltage is applied across the high load circuitry 115 and the low load circuitry 120, the magnitude of the low load current signal will be smaller than the magnitude of the high load current signal because the second resistance of the second resistor is larger than the first resistance of the first resistor.

The control system 100 is shown to include a frequency switcher 140 to adjust or otherwise alter a frequency of the low load current signal. In some embodiments, the frequency switcher 140 may include amplifiers or other circuitry to increase the frequency of the low load current signal, such that the frequency of the low load current signal is higher than the frequency of the high load current signal. By way of example, the frequency switcher 140 may adjust the frequency of the low load current signal to be a 180 kHz square wave with a 50% duty cycle.

The control system 100 is shown to include a controller 125 to adjust or otherwise manipulate the high load current signal from the high load circuitry 115 and/or the low load current signal from the low load circuitry 120. The controller 125 is shown to include at least one processor 130 and memory 135. The processor 130 may issue commands to and process information from other components. The processor 130 may be implemented as a specific purpose processor, an application specific integrated circuit (ASIC), one or more field programmable gate arrays (FPGAs), a group of processing components, or other suitable electronic processing components. The memory 135 may include one or more devices (e.g., RAM, ROM, flash memory, hard disk storage) for storing data and computer code for completing and facilitating the various user or client processes, layers, and modules described in the present disclosure. The memory 135 may be or include volatile memory or non-volatile memory and may include database components, object code components, script components, or any other type of information structure for supporting the various activities and information structures of the inventive concepts disclosed herein. The memory 135 may be communicably coupled to the processor 130 and include computer code or instruction modules for executing one or more processes described herein.

The controller 125 is shown to optionally include frequency adjustment controls 150 to select or otherwise adjust the frequency settings of the frequency switcher 140. In some embodiments, the controller 125 may use (e.g., activate, enable, etc.) the frequency adjustment controls 150 based on the performance of the control system 100 in triggering (e.g., activating, switching) the AFCI device 155. By way of example, the controller 125 may automatically adjust the frequency of the low load current signal if the control system 100 is not successful in triggering the AFCI device 155 after a predetermined time period of attempting to trigger the AFCI device 155 at a certain frequency. By way of another example, the controller 125 may adjust the frequency of the low load current signal via the frequency adjustment controls 150 responsive to an operator (e.g., user) interaction with a user interface 137 of the control system 100 (e.g., to set the frequency to a certain setpoint).

The controller 125 is shown to include a load switching circuit 145 to set (e.g., maintain) a pulse width of the high load current signal. In some embodiments, the load switching circuit 145 comprises a single driver circuit configured to control both the high load current signal and the low load current signal, rather than using separate driver circuits for each signal. Using a single driver circuit to control both signals may reduce circuit complexity and require fewer I/O pins. In some embodiments, the load switching circuit 145 may select a certain pulse width for the high load current signal. By way of example, if a desired pulse width (e.g., a pulse width determined by the load switching circuit 145, set by an operator) is 5 milliseconds (ms), the load switching circuit 145 may switch on (e.g., enable, engage) the high load current signal for 5 ms before switching off (e.g., disabling, disengaging) the load switching circuit 145 for another 5 ms. In some embodiments, the desired pulse width of the load switching circuit 145 is a range of times rather than a specific time setpoint. By way of example, if the desired pulse width is between 4 ms and 6 ms, the load switching circuit 145 may switch on the high load current signal for any amount of time between 4 ms and 6 ms before switching off (e.g., disabling, disengaging) the load switching circuit 145 for an amount of time between 4 ms and 6 ms.

The load switching circuit 145 may be configured to set the pulse width of both the high load current signal and the low load current signal simultaneously. For example, when the load switching circuit 145 switches on the high load current signal, the load switching circuit 145 may also switch on the low load current signal. By way of example, if the desired pulse width for the high load current signal is 5 ms, the load switching circuit 145 may switch on (e.g., enable, engage) the low load current signal for the same 5 ms as the high load current signal before switching off both the high load current signal and the low load current signal for another 5 ms. As such, the load switching circuit 145 may allow for both the high load current signal and the low load current signal to be switched on by a single controller 125 and allow for the pulse widths of the high load current signal and the low load current signal to be equal (e.g., synchronized). The high frequency, low load current signal may be overlayed with the high load current signal at the same pulse width, such that the resulting pulse is not different in amplitude or width from the perspective of the switching timing.

The pulse width of the high load current signal and the low load current signal may be based on a duration of a cycle of the high load current signal and the low load current signal. For example, if there are 5 cycles (e.g., including a pulse and a pause) in one second, the pulse width of the high load current signal may be 0.1 seconds followed by a 0.1 second pause. Each cycle may be divided into two half cycles. A first half cycle of the cycle may correspond to switching on the high and low load current signals, and the second half cycle may correspond to switching off the high and low load current signals. These half cycles may be equal in duration, or may be different in duration.

The load switching circuit 145 may determine or otherwise select the duration of one or more half cycles to pulse (e.g., switch on) the high and low load current signals. For example, the load switching circuit 145 may select between 8 and 12 pulses every 0.5 seconds. In other embodiments, the load switching circuit 145 may select a different number of pulses every 0.5 seconds. By way of example, if the high load current signal is 60 Hz, the load switching circuit 145 may select between 8 and 12 half cycles (e.g., of the 60 total half cycles) to apply pulses to. The load switching circuit 145 may be configured to adjust or otherwise change the selection of half cycles, such that the pattern of pulses is not constant (e.g., changeable). By way of example, a first pattern may include selecting a first 8-12 half cycles, and a second pattern may include selecting a second 8-12 half cycles. The first 8-12 half cycles may be the same as the second 8-12 half cycles, or may be different half cycles. The selected half cycles may be either consecutive half cycles or non-consecutive half cycles. The load switching circuit 145 may select the same half cycles for the low load current signal and the high load current signal, such that the low load current signal and high load current signal is switched at the same time for an equal duration.

The control system 100 may be configured to overlay or otherwise combine the selected low load current signal pulses with the selected high load current signal pulses. As described above, the low load current signal may be adjusted by the frequency switcher 140 such that the low load current signal has a higher frequency than the high load current signal. In some embodiments, the low load current signal and the high load current signal are overlayed (e.g., combined) into a single test signal. The test signal may include the high load current pulses offset by the high frequency, low load current pulses. The test signal may be configured to mimic (e.g., appear similar to) a parallel arcing signal. In some embodiments, the test signal may also be configured to mimic a series arcing signal. Beneficially, AFCIs from various manufacturers may not open or break the circuit without detecting noise, which is imitated by the low load current signal in the test signal. The addition of the low load current signal to the testing signal therefore may allow the control system 100 to test a wider variety of AFCIs that are sensitive to such noise.

The test signal may be transmitted or otherwise sent to the AFCI device 155. The control system 100 may include sensors, shown as sensors 160, or other devices to determine whether the AFCI device 155 was triggered (e.g., activated) by the test signal. By way of example, the control system 100 may include a sensor 160 (e.g., ammeter) to detect a break in the circuit between the control system 100 and the AFCI device 155. In the event that the test signal does not trigger the AFCI device 155, the control system 100 may be configured to facilitate adjustment of the test signal to reattempt triggering the AFCI device 155. In some embodiments, the control system 100 may adjust at least one of a frequency of the low load current signal (e.g., using the frequency switcher 140), a pulse width of the test signal (e.g., using the load switching circuit 145), and/or selecting a different pattern of half cycles to be used for the test signal (e.g., using the load switching circuit 145).

The control system 100 may include a user interface, shown as user interface 137, configured to receive operator commands and/or display information relating to the performance of the control system 100 in triggering the AFCI device 155. For example, the user interface 137 may include a display, one or more buttons, one or more switches, or other components to receive operator commands and display data. The user interface 137 may be disposed on the housing, and/or may be a device remote of (e.g., external to) the housing. In some embodiments, the user interface 137 may transmit an instruction to the controller 125 to adjust the test signal responsive to operator inputs. By way of example, the operator may interact with the user interface 137 to instruct the controller 125 to adjust a frequency of the low load current signal, adjust a pulse width of the test current, and/or select a pattern of half cycles for the test signal. In some embodiments, the user interface 137 may display information relating to the performance of the control system 100 in triggering of the AFCI device 155. By way of example, if a sensor 160 of the control system 100 detects or otherwise determines that there is a break in the circuit, the user interface 137 may display a message or an indication that the AFCI device 155 has been triggered. By way of another example, the user interface 137 may display a message indicating that the test signal is currently being transmitted to the AFCI device 155.

In some embodiments, the control system 100 includes a sensor 160 or other circuitry that may measure a temperature of the components of the control system 100 (e.g., high load circuitry 115, low load circuitry 120, rectifier circuitry 110) and/or an ambient temperature within the housing. Based on receiving temperature data indicating a measured temperature associated with the components of the control system 100, the control system 100 may selectively disable or otherwise shut itself off. By way of example, if the temperature of one or more components of the control system 100 is above a predetermined threshold temperature, the control system 100 may disable operation until the temperature falls below the threshold. As such, the sensor 160 may prevent damage from occurring to the control system 100 due to overheating.

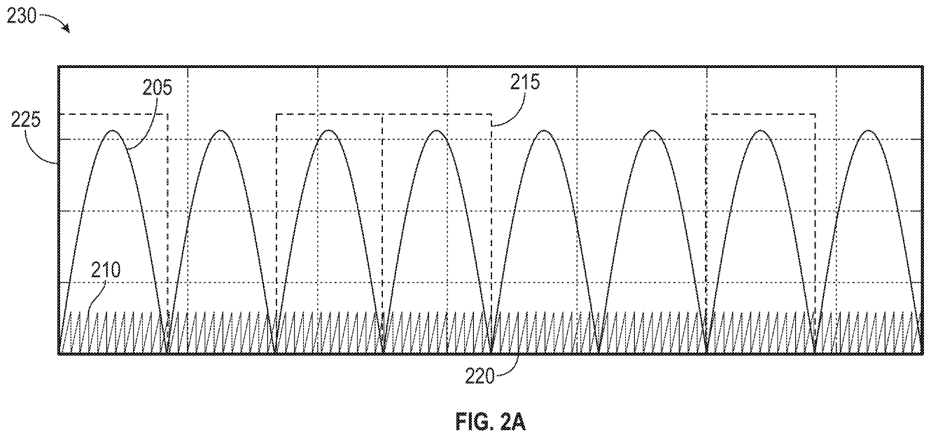

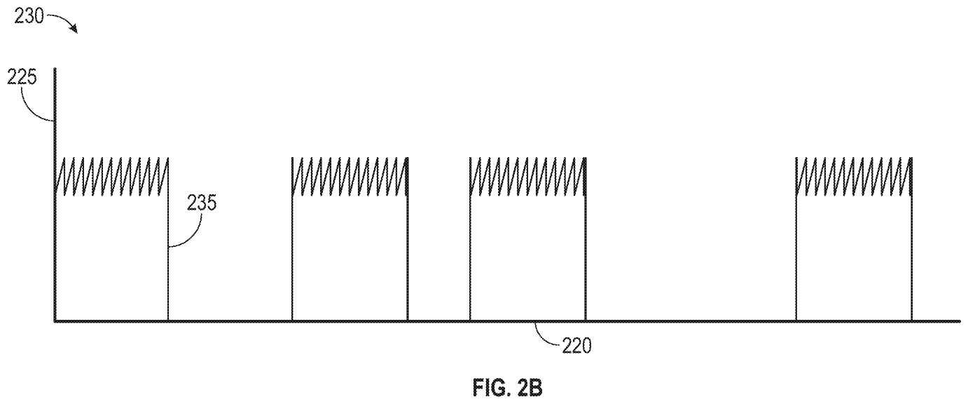

Referring to FIG. 2A, depicted is a graph 200 of the high and low load current signals, according to an example embodiment. Graph 200 is shown to include a horizontal axis 220. The horizontal axis 220 may be scaled (e.g., distributed) based on time. By way of example, a first point (e.g., position) on the horizontal axis 220 may be a first time instance, and a second point on the horizontal axis 220 may be a second time instance. Graph 200 is shown to include a vertical axis 225. The vertical axis 225 may be scaled (e.g., distributed) based on voltage or current amplitude. By way of example, a first point on the vertical axis 225 may be a first current value and a second point on the vertical axis 225 may be a second current value. Graph 200 is shown to include a high load current signal 205. The high load current signal 205 is shown to include a plurality of positive half cycles. In some embodiments, the frequency of the high load current signal 205 is 60 Hz. In other embodiments, the frequency of the high load current signal 205 is a different frequency. As shown, the graph 200 does not include any negative voltages (e.g., corresponding to negative half cycles). This may be caused by an AC signal (e.g., from the power source 105) being rectified (e.g., by the rectifier circuitry 110) such that the negative half cycles have a positive voltage. For example, a first half cycle may correspond to a positive half cycle of an AC signal, and a second half cycle adjacent to the first half cycle may be a negative half cycle that is rectified such that it has a positive voltage.

Graph 200 is shown to include a low load current signal 210. The low load current signal 210 is shown to include a plurality of positive half cycles. As evidenced by the larger number of half cycles of the low load current signal 210 relative to the number of half cycles of the high load current signal 205, the low load current signal 210 has a higher frequency than the high load current signal 205. By way of example, the frequency of the low load current signal 210 is 180 kHz. The amplitude of the high load current signal 205 is shown to be larger than the amplitude of the low load current signal 210. By way of example, the amplitude of the low load current signal 210 may be approximately one-tenth of the amplitude of the high load current signal 205.

Referring to FIGS. 1 and 2A, the graph 200 is shown to include a plurality of selected half cycles 215 to be used for the test signal. The controller 125 may select the plurality of selected half cycles 215 based on a predetermined pattern of half cycles, or based on a random or pseudo-random (e.g., not predetermined) selection. It should be understood that the plurality of selected half cycles 215 may include any number of half cycles, and in various implementations of the control system 100, the controller 125 may select any arrangement of half cycles to be used in the test signal. By way of example, the number of selected half cycles 215 may be between 8 and 12 half cycles of the high load current signal 205 and the corresponding half cycles of the low load current signal 210 every 0.5 seconds. The selected half cycles 215 may be any combination of consecutive and/or nonconsecutive half cycles. For example, the controller 125 may select a first half cycle and a second half cycle that are adjacent to one another. As another example, the controller 125 may select a first half cycle and may not select a second half cycle adjacent to the first half cycle.

Referring to FIG. 2B, depicted is a graph 230 of a test signal 235, according to an example embodiment. The graph 230 is shown to include the horizontal axis 220, and the vertical axis 225. The test signal 235 is shown to include a plurality of pulses of equal width. In some embodiments, the test signal 235 is a pulsed square wave. For example, the pulsed square wave may include a ripple corresponding to a low load current signal 210 that is offset on the vertical axis 225 by the amplitude of a high load current signal 205.

Referring to FIGS. 1, 2A, and 2B, the test signal 235 is shown to be an overlay of the high load current signal 205 and the low load current signal 210 at the selected half cycles 215. In some embodiments, the width of each pulse of the test signal 235 is based on a pulse width determined by the load switching circuit 145. By way of example, each pulse of the test signal 235 may be 5 ms. By way of another example, each pulse of the test signal 235 may be between 4 ms and 6 ms. The load switching circuit 145 may determine the portion (e.g., part, section) of each selected half cycle 215 for applying the pulse to. By way of example, if the load switching circuit 145 determines that each pulse should be a first time length, and each half cycle is a second time length, the load switching circuit 145 may determine a portion of the second time length to apply the pulse for the first time length.

Advantageously, overlaying the high load current signal 205 and the low load current signal 210 may result in a test signal that is more broadly applicable to various AFCI devices 155 (e.g., AFCI devices from various different manufacturers). For example, certain AFCI devices 155 may be sensitive to noise caused by parallel arcing. By overlaying the low load current signal 210 onto the high load current signal 205, the low load current signal 210 may simulate noise that resembles parallel arcing. As another example, certain AFCI devices 155 may be sensitive to asynchronous pulses. By selecting a certain pattern of selected half cycles 215 to use for the test signal 235, the controller 125 may generate the test signal 235 that is most likely to trigger a respective AFCI device 155. Additionally, the use of a single driver circuit to control both the high load current signal 205 and the low load current signal 210 simplifies the circuitry while still enabling accurate breaker testing across devices from various manufacturers. This simplified architecture requires fewer I/O pins compared to systems that use separate driver circuits for each load.

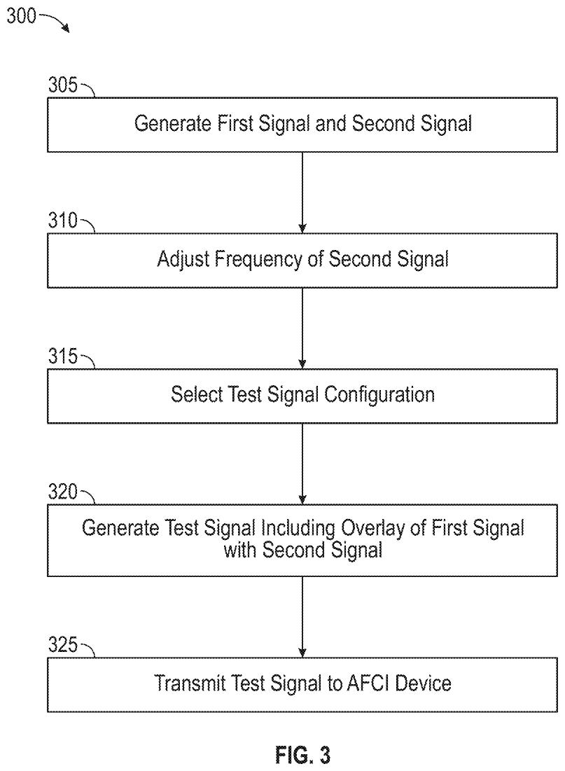

Referring to FIG. 3, depicted is a flow diagram of a method 300 for generating the test signal 235 for the AFCI device 155, according to an example embodiment. One or more steps of the method 300 may be performed by the control system 100, or one or more components thereof. It will be appreciated that the steps of method 300 are not intended to be limiting, such that the method 300 may include more or fewer steps than those shown and that the steps of method 300 may be completed in any order.

Referring to FIGS. 1 and 3, at step 305, the control system 100 may generate a first signal and a second signal. The first signal may be the high load current signal 205. The second signal may be the low load current signal 210. The high load current signal 205 may be generated responsive to electricity from the power source 105 being transmitted to the rectifier circuitry 110 and/or the high load circuitry 115. The low load current signal 210 may be generated responsive to electricity from the power source 105 being transmitted to the rectifier circuitry 110 and/or the low load circuitry 120.

At step 310, the control system 100 may adjust a frequency of the second signal. For example, the frequency switcher 140 may adjust the frequency of the second signal. The adjusted frequency may be based on a selection (e.g., determination) using frequency adjustment controls 150 of the control system 100. In some embodiments, the frequency of the second signal may be adjusted to be higher than the frequency of the first signal. By way of example, the frequency of the first signal may be approximately 60 Hz and the frequency of the second signal may be approximately 180 kHz.

At step 315, the control system 100 may select a test signal configuration. The control system 100 may select one or more half cycles of the first signal to apply a pulse to. The number of half cycles may be based on a desired number of pulses in a predetermined period of time. By way of example, the number of pulses may be between 8 and 12 pulses every 0.5 seconds. The controller 125 may select a pulse width for each of the selected half cycles. The pulse width may be any length that is less than or equal to the length of the half cycle. By way of example, for a half cycle that is 8.3 ms long, the selected pulse width may be between 4 ms and 6 ms. As another example, if the half cycle is 8.3 ms long, the pulse width may be less than 4 ms or between 6 ms and 8.3 ms.

At step 320, the control system 100 may generate the test signal 235 by overlaying the first signal with the second signal. The overlay of the first signal and the second signal may be based on the test signal configuration selected by the controller 125. By way of example, the load switching circuit 145 may switch on the first signal and the second signal at the selected half cycles of the first signal for the selected pulse width. The test signal 235 may be a pulsed square wave with a ripple at a top portion of each pulse (e.g., corresponding to the second signal). For example, the ripple may correspond to the frequency of the second signal offset by the amplitude of the first signal.

At step 325, the control system 100 may transmit the test signal 235 to the AFCI device 155. In some embodiments, the control system 100 may include sensors 160 or other devices to determine whether the test signal 235 successfully triggered (e.g., tripped, activated, etc.) the AFCI device 155. Based on whether the AFCI device 155 was successfully triggered, the test signal configuration may be adjusted, and subsequent test signals 235 may be transmitted to the AFCI device 155. For example, if the AFCI device 155 is not triggered by the test signal 235, the controller 125 may reconfigure the test signal 235 by selecting different half cycles and/or adjusting the frequency of the second signal. As another example, if the AFCI device 155 is triggered by the test signal 235, the controller 125 may terminate transmission of the test signal 235, and may display an indication to the user interface 137 indicating that the AFCI device 155 was triggered successfully.

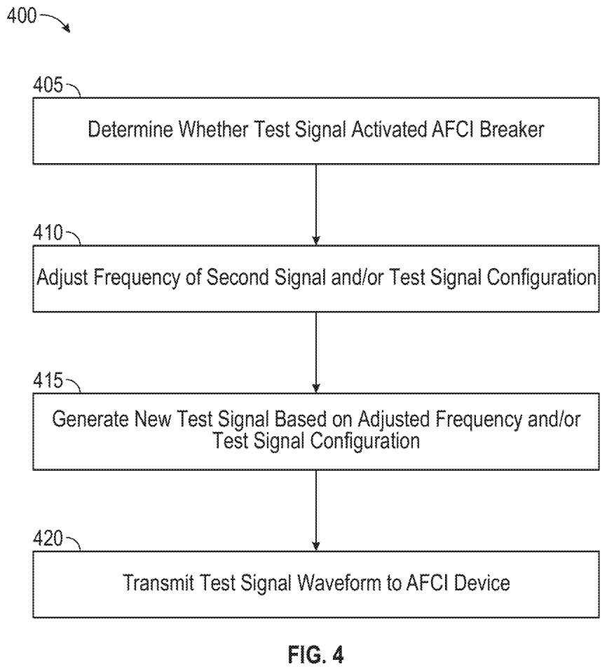

Referring to FIG. 4, depicted is a flow diagram of a method 400 for testing AFCI devices 155, according to an example embodiment. One or more steps of the method 400 may be performed by the control system 100. It will be appreciated that the steps of method 400 are not intended to be limiting, such that the method 400 may include more or fewer steps than those shown and that the steps of method 400 may be completed in any order. For example, the method 400 may be performed in sequence with the method 300.

Referring to FIGS. 1 and 4, at step 405, one or more sensors of the control system 100 (e.g., sensors 160) may determine whether the test signal (e.g., the test signal 235) activated or otherwise triggered the AFCI device 155. By way of example, the control system 100 may include the sensor 160, such as a the current sensor, placed between the control system 100 and the AFCI device 155 to determine the presence of a break in the circuit (e.g., whether current is returned from the AFCI device 155). If the sensor 160 detects no current returned from the AFCI device 155 (e.g., flowing through the circuit), the sensor 160 may detect that the test signal 235 triggered the AFCI device 155. If the sensor 160 detects current flowing through the circuit, the sensor 160 may detect that the test signal 235 did not trigger the AFCI device 155.

At step 410, if the sensor 160 determines that the AFCI device 155 is not activated (e.g., detects no break in the circuit) the control system 100 may re-attempt to trigger the AFCI device 155 by adjusting the test signal 235. For example, the control system 100 may adjust the frequency of the second signal 210 and/or the test signal configuration (e.g., the pulse width and/or the arrangement of selected half cycles 215). In some embodiments, the control system 100 may adjust the frequency of the second signal 210 by transmitting an instruction from the frequency adjustment controls 150 to the frequency switcher 140 indicating a frequency adjustment. In some embodiments, the load switching circuit 145 may adjust at least one of the pulse width or the selection (e.g., pattern) of selected half cycles for the test signal 235.

At step 415, the control system 100 may generate a new test signal 235 based on the adjusted frequency and/or the test signal configuration. The test signal 235 may include an overlay of a first signal (e.g., the high load current signal 205) and the second signal (e.g., the low load current signal 210). For example, if the frequency of the second signal 210 was adjusted, the new test signal 235 may include an overlay of the first signal and the adjusted second signal. The ripple of the new test signal 235 may be based on the frequency of the second signal 210. If the test signal configuration was adjusted, the new test signal 235 may include a different pulse width and/or half cycle selection than the previous test signal 235.

At step 420, the control system 100 may transmit the test signal 235 to the AFCI device 155. In some embodiments, the control system 100 may include sensors 160 or other devices configured to determine whether the test signal 235 successfully triggered (e.g., tripped, activated, etc.) the AFCI device 155. Based on whether the AFCI device 155 was successfully triggered, the test signal configuration may be adjusted, and subsequent test signals 235 may be transmitted to the AFCI device 155. In some embodiments, there may be a threshold number of test signals 235 that may be attempted by the control system 100 before the operator is notified (e.g., via the user interface 137 or other indication). For example, the notification may indicate that the AFCI device 155 is faulty (e.g., broken, damaged, not working properly, etc.).

It should be noted that the terms “exemplary” and “example” as used herein to describe various embodiments is intended to indicate that such embodiments are possible examples, representations, and/or illustrations of possible embodiments (and such term is not intended to connote that such embodiments are necessarily extraordinary or superlative examples).

The terms “coupled,” “connected,” and the like, as used herein, mean the joining of two members directly or indirectly to one another. Such joining may be stationary (e.g., permanent, etc.) or moveable (e.g., removable, releasable, etc.). Such joining may be achieved with the two members or the two members and any additional intermediate members being integrally formed as a single unitary body with one another or with the two members or the two members and any additional intermediate members being attached to one another.

References herein to the positions of elements (e.g., “top,” “bottom,” “above,” “below,” “between,” etc.) are merely used to describe the orientation of various elements in the figures. It should be noted that the orientation of various elements may differ according to other exemplary embodiments, and that such variations are intended to be encompassed by the present disclosure.

Also, the term “or” is used in its inclusive sense (and not in its exclusive sense) so that when used, for example, to connect a list of elements, the term “or” means one, some, or all of the elements in the list. Conjunctive language such as the phrase “at least one of X, Y, and Z,” unless specifically stated otherwise, is otherwise understood with the context as used in general to convey that an item, term, etc. may be either X, Y, Z, X and Y, X and Z, Y and Z, or X, Y, and Z (i.e., any combination of X, Y, and Z). Thus, such conjunctive language is not generally intended to imply that certain embodiments require at least one of X, at least one of Y, and at least one of Z to each be present, unless otherwise indicated.

It is important to note that the construction and arrangement of the systems as shown in the exemplary embodiments is illustrative only. Although only a few embodiments of the present disclosure have been described in detail, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter recited. For example, elements shown as integrally formed may be constructed of multiple parts or elements. It should be noted that the elements and/or assemblies of the components described herein may be constructed from any of a wide variety of materials that provide sufficient strength or durability, in any of a wide variety of colors, textures, and combinations. Accordingly, all such modifications are intended to be included within the scope of the present inventions. Other substitutions, modifications, changes, and omissions may be made in the design, operating conditions, and arrangement of the preferred and other exemplary embodiments without departing from scope of the present disclosure or from the spirit of the appended claims.

Although the figures and description may illustrate a specific order of method steps, the order of such steps may differ from what is depicted and described, unless specified differently above. Also, two or more steps may be performed concurrently or with partial concurrence, unless specified differently above. Such variation may depend, for example, on the software and hardware systems chosen and on designer choice. All such variations are within the scope of the disclosure. Likewise, software implementations of the described methods could be accomplished with standard programming techniques with rule-based logic and other logic to accomplish the various connection steps, processing steps, comparison steps, and decision steps.

What is claimed is:

1. An arc fault circuit interrupter (AFCI) device testing system, comprising:
a housing;
a load switching circuit disposed within the housing and configured to receive a first signal and a second signal; and
a controller disposed within the housing operatively coupled to the load switching circuit, comprising one or more processors configured to:
cause adjustment of a frequency of the second signal to be higher than a frequency of the first signal;
generate a test signal comprising an overlay of the first signal with the second signal; and
transmit the test signal to an AFCI device.

2. The system of claim 1, wherein the load switching circuit is configured to receive an alternating current (AC) signal, and wherein the system further comprises:
a rectifier configured to adjust one or more negative half cycles of the AC signal such that the one or more negative half cycles have a positive voltage.

3. The system of claim 1, wherein the controller is configured to generate the test signal by selecting at least one half cycle of a plurality of half cycles of the first signal.

4. The system of claim 1, comprising a temperature sensor configured to measure a temperature of at least one of the load switching circuit or an environment within the housing, wherein the one or more processors are further configured to:
receive temperature data from the temperature sensor indicating a temperature of the load switching circuit or the environment;
determine whether the temperature is above a predetermined threshold; and
responsive to a determination that the temperature is above the predetermined threshold, disable transmission of the test signal until the temperature is below the predetermined threshold.

5. The system of claim 1, wherein the frequency is a first frequency, wherein the controller is configured to adjust the frequency of the second signal to be a second frequency, and wherein the first frequency is different from the second frequency.

6. The system of claim 1, wherein the test signal comprises a first pulse of the first signal overlayed with a second pulse of the second signal, and wherein a pulse width of the first pulse is equal to a pulse width of the second pulse.

7. The system of claim 1, wherein a pulse width of the test signal is between 4 milliseconds and 6 milliseconds.

8. The system of claim 1, wherein an amplitude of the first signal is larger than an amplitude of the second signal.

9. The system of claim 1, comprising an interface configured to electronically couple the load switching circuit and an AFCI device located externally of the housing, wherein the one or more processors are configured to transmit the test signal to the AFCI device.

10. A method for testing arc fault circuit interrupter (AFCI) devices, comprising:
receiving, by one or more processors of a load switching circuit, a first signal and a second signal;
causing, by the one or more processors, adjustment of a frequency of the second signal;
determining, by the one or more processors, a desired pulse pattern for a test signal comprising the first signal and the second signal; and
generating, by the one or more processors, the test signal at the desired pulse pattern, the test signal comprising an overlay of the first signal with the second signal.

11. The method of claim 10, comprising selecting, by the one or more processors, one or more half cycles of the first signal to be included in the desired pulse pattern for the test signal.

12. The method of claim 10, wherein the frequency is a first frequency, comprising adjusting, by the one or more processors, the frequency of the second signal to be a second frequency, wherein the first frequency and the second frequency are different.

13. The method of claim 10, comprising:
receiving, by the one or more processors, temperature data from a temperature sensor indicating a temperature of a load switching circuit or an environment within a housing;
determining, by the one or more processors, whether the temperature is above a predetermined threshold; and
responsive to a determination that the temperature is above the predetermined threshold, disabling, by the one or more processors, transmission of the test signal until the temperature is below the predetermined threshold.

14. The method of claim 10, wherein the test signal comprises a first pulse of the first signal and a second pulse of the second signal, comprising synchronizing, by the one or more processors, switching of the first signal and the second signal, such that the first pulse and the second pulse are switched at the same time, and the first pulse and the second pulse match a pulse width of the test signal.

15. The method of claim 10, comprising transmitting, by the one or more processors, the test signal to the AFCI device located externally of a housing where the one or more processors are disposed.

16. The method of claim 10, wherein the frequency of the second signal is adjusted to be a higher frequency than the first signal.

17. The method of claim 10, wherein the test signal is a first test signal, the frequency is a first frequency, and the desired pulse pattern is a first desired pulse pattern, comprising:
determining, by the one or more processors, whether the first test signal activated an AFCI device;
at least one of (a) adjusting, by the one or more processors, the frequency of the second signal to be a second frequency, or (b) adjusting, by the one or more processors, the desired pulse pattern to be a second desired pulse pattern; and
generating, by the one or more processors, the test signal at the second desired pulse pattern.

18. One or more non-transitory storage media storing instructions thereon that, when executed by one or more processors, cause the one or more processors to perform operations comprising:
receiving a first signal and a second signal;
causing adjustment of a frequency of the second signal;
determining a desired pulse pattern for a test signal comprising the first signal and the second signal; and
generating the test signal at the desired pulse pattern, the test signal comprising an overlay of the first signal with the second signal.

19. The one or more non-transitory storage media of claim 18, wherein the test signal is a first test signal, the frequency is a first frequency, and the desired pulse pattern is a first desired pulse pattern, and wherein the instructions further cause the one or more processors to perform operations comprising:
determining whether the first test signal activated an arc fault circuit interrupter (AFCI) device;
at least one of (a) adjusting the frequency of the second signal to be a second frequency, or (b) adjusting the desired pulse pattern to be a second desired pulse pattern; and
generating, by the one or more processors, the test signal at the second desired pulse pattern.

20. The one or more non-transitory storage media of claim 18, wherein the test signal comprises a first pulse of the first signal and a second pulse of the second signal, and wherein the instructions cause the one or more processors to perform operations comprising synchronizing, by the one or more processors, switching of the first signal and the second signal, such that a pulse width of the first pulse is equal to a pulse width of the second pulse.
